(19) United States
(12) Patent Application Publication
(10) Pub. No.: US 2016/0233148 A1
(43) Pub. Date: Aug. 11, 2016

(54) SEMICONDUCTOR PACKAGE STRUCTURE INCLUDING HEAT DISSIPATION ELEMENTS

(71) Applicant: ILI TECHNOLOGY CORPORATION, Jhubei City (TW)

(72) Inventors: Chih-Hung LU, Hsinchu City (TW); Shih-Fong LIN, Jhunan Township (TW)

(21) Appl. No.: 14/849,345

(22) Filed: Sep. 9, 2015

(30) Foreign Application Priority Data
Feb. 6, 2015 (TW) 104104082

(51) Int. Cl. H01L 23/498; H01L 23/373; H01L 23/31; H01L 23/367

(52) U.S. Cl. CPC H01L 23/4985; H01L 23/49833; H01L 23/3675; H01L 23/3736; H01L 23/49838; H01L 23/3135

(57) ABSTRACT

A semiconductor package structure includes a flexible substrate, a semiconductor element, a printed circuit board, and first and second heat dissipation elements. The flexible substrate includes first and second insulation layers, and a first wiring layer including input and output ends. The semiconductor element is connected to the first wiring layer. The printed circuit board is disposed adjacent to the input end and includes a second wiring layer connected to the first wiring layer. The first heat dissipation element is connected to the printed circuit board and spaced apart from the second wiring layer. The second heat dissipation element has a main portion and a first extension portion extending to contact the first heat dissipation element.

### CROSS-REFERENCE TO RELATED APPLICATION

This application claims priority of Taiwanese Patent Application No. 104104082, filed on Feb. 6, 2015.

### FIELD

The disclosure relates to a semiconductor package structure, more particularly to a semiconductor package structure that is used in a display panel and that includes heat dissipation elements.

### BACKGROUND

With the development of liquid crystal display technology, it is now a common requirement for refresh rates of 4k HD displays (having a resolution of 3840 ×2160 pixels) and three dimensional (3D) displays to be increased from 60 Hz to 120 Hz. The requisite rise in refresh rates has greatly increased the loading of display driver integrated circuits (IC). During operation, if the heat generated by the display driver IC is not dissipated efficiently, hot spots will be formed in certain regions of the display driver IC and will cause IC malfunction.

Referring to FIG. 1, a conventional semiconductor package structure 1 (similar to the semiconductor package structure disclosed in US 2008/0023822 A1) is disposed between and connected to a display panel 2 and a printed circuit board 3.

The semiconductor package structure 1 includes a flexible substrate 11, a driver IC 12 disposed on the flexible substrate 11, an aluminum heat dissipation element 13 disposed on the flexible substrate 11, and a reinforcement element 14 disposed on the heat dissipation element 13. The heat dissipation element 13 is disposed between the driver IC 12 and the reinforcement element 14. The flexible substrate 11 includes spaced-apart input and output ends 111, 112. The input end 111 is connected to the printed circuit board 3. The output end 112 is connected to the display panel 2.

The display panel 2 has a back surface 21 that is adjacent to a backlight unit (not shown), and a front surface 22 that is laminated with a polarizer (not shown) and that is used for displaying an image. A frame unit is used for assembling the semiconductor package structure 1, the display panel 2 and the backlight unit therein to form a liquid crystal display module.

Heat generated in the semiconductor package structure 1 can be dissipated from the driver IC 12 to two ends of the flexible substrate 11 via the heat dissipation element 13. That is, an effective heat dissipation region of the semiconductor package structure 1 is limited to the two ends of the flexible substrate 11. Furthermore, with the miniaturized and lightweight requirements for a display module, the frame unit 4 that contacts the semiconductor package structure 1 is usually made of a lightweight reinforced plastic material instead of aluminum. The reinforced plastic material is a composite material that includes a major component of epoxy resin having a thermal conductivity of about 0.19 W/mK. Compared with aluminum, having a thermal conductivity of about 237 W/mK, the reinforced plastic material is less effective in terms of heat dissipation.

Due to the abovementioned problem of inefficient heat dissipation, during operation, the temperature and size of the hot spots will continuously increase, causing more hot spots to form in the flexible substrate 11 and resulting in IC malfunction and deteriorated display quality.

### SUMMARY

Therefore, an object of the disclosure is to provide a semiconductor package structure that has improved heat dissipation capability, so that temperatures at hot spots can be lowered and IC malfunction can be prevented.

According to an aspect of the present disclosure, a semiconductor package structure includes a flexible substrate, a semiconductor element, a printed circuit board, a first heat dissipation element and a second heat dissipation element.

The flexible substrate includes first and second insulation layers, and a first wiring layer that is disposed between the first and second insulation layers and that includes input and output ends. The semiconductor element is disposed on and electrically connected to the first wiring layer. The printed circuit board is disposed adjacent to the input end of the first wiring layer and includes a second wiring layer that is electrically connected to the first wiring layer. The first heat dissipation element is disposed on and connected to the printed circuit board and is spaced apart from the second wiring layer. The second heat dissipation element has a main portion that is disposed on and connected to either one of the first and second insulation layers, and a first extension portion that connects and extends outwardly from the main portion to contact the first heat dissipation element on the printed circuit board.

### BRIEF DESCRIPTION OF THE DRAWINGS

Other features and advantages of the present disclosure will become apparent in the following detailed description of the embodiments with reference to the accompanying drawings, of which:

FIG. 1 is a fragmentary, partly cross-sectional view of a conventional semiconductor package structure;

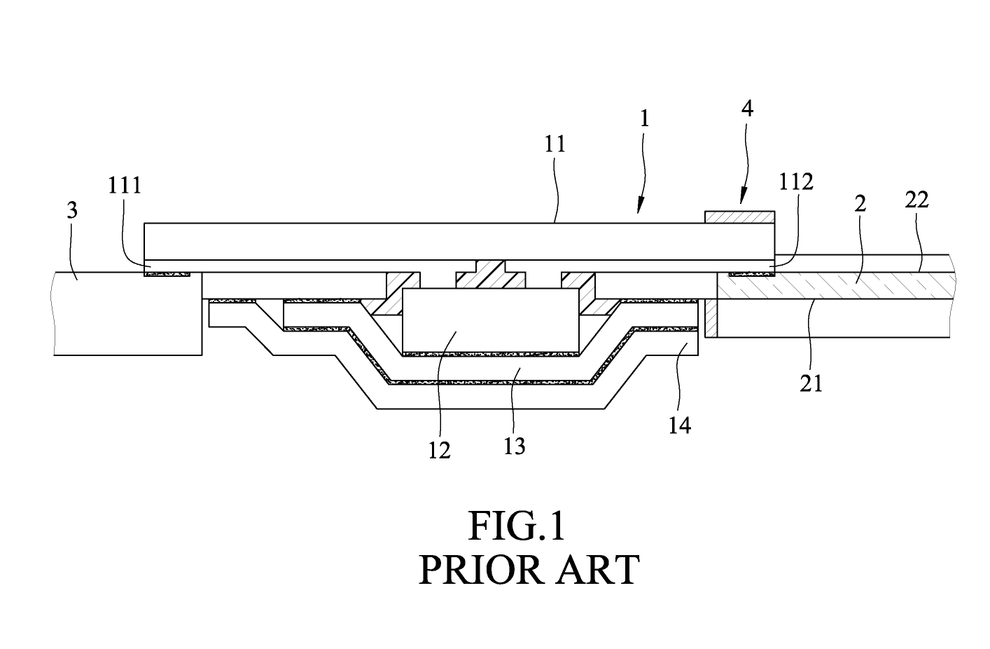

FIG. 2 is a fragmentary perspective view of a first embodiment of a semiconductor package structure according to the present disclosure;

FIG. 3 is a fragmentary, partly cross-sectional view of the first embodiment taken along line III-III of FIG. 2;

FIG. 4 is a fragmentary perspective view of a second embodiment of the flexible substrate semiconductor package structure according to the present disclosure;

FIG. 5 is a fragmentary, partly cross-sectional view of the second embodiment taken along line V-V of FIG. 4;

FIG. 6 is a fragmentary perspective view of a third embodiment of the flexible substrate semiconductor package structure according to the present disclosure; and

FIG. 7 is a fragmentary, partly cross-sectional view of the third embodiment taken along line VII-VII of FIG. 6.

### DETAILED DESCRIPTION

Before the disclosure is described in greater detail with reference to the accompanying embodiments, it should be noted herein that like elements are denoted by the same reference numerals throughout the disclosure.

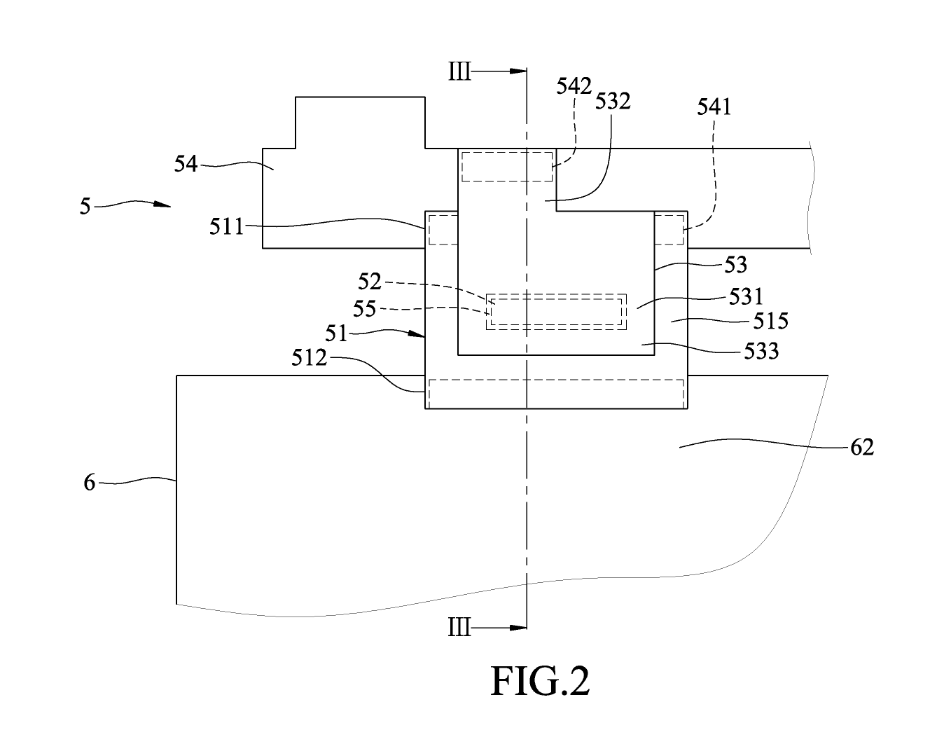

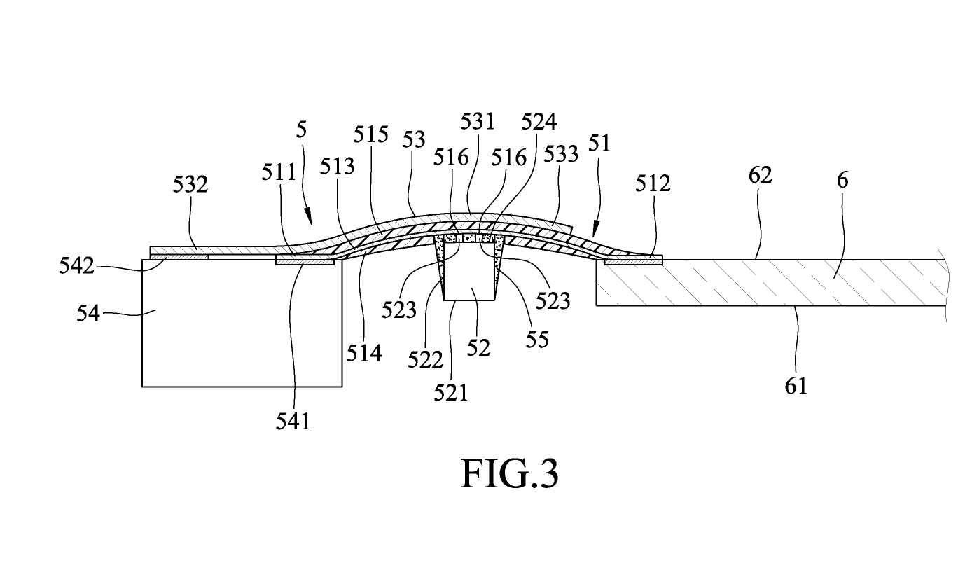

Referring to FIGS. 2 and 3, a first embodiment of a semiconductor package structure 5 according to the present disclosure is adapted to be used with a display panel 6 of a display module, and includes a flexible substrate 51, a semiconductor element 52, a printed circuit board 54, a first heat dissipation element 542 and a second heat dissipation element 53. The display panel 6 has a back surface 61 that is adjacent to a backlight unit (not shown), and a front surface 62 that is laminated with a polarizer (not shown) and that is used for displaying an image.

It is worth mentioning that the display panel 6 may be a liquid crystal display panel or an active matrix organic light emitting diode (AMOLED) display panel.

The flexible substrate 51 includes first and second insulation layers 514, 515, and a first wiring layer 513 that is disposed between the first and second insulation layers 514, 515, that includes spaced-apart input and output ends 511, 512, and that has two spaced-apart connection portions 516. The connection portions 516 are exposed from the first insulation layer 514 and are spaced apart from the input end 511. The first wiring layer 513 is made of copper, which has superior electrical and thermal conductivities. The second insulation layer 515 may be used as a support layer and may be made of polyimide (PI) film. The first insulation layer 514 may be used as a solder resist layer, may be mainly made of polyimide resin, and is used for protecting the first wiring layer 513.

In the first embodiment, the semiconductor element 52 is a driver IC. The semiconductor element 52 is disposed between the input and output ends 511, 512, and is disposed on and electrically connected to the first wiring layer 513. The semiconductor element 52 has top and bottom surfaces 521, 524, a lateral surface 522 interconnecting the top and bottom surfaces 521, 524, and two spaced-apart connection members 523 that are formed on and extend from the bottom surface 524 oppositely of the top surface 521 to respectively contact the connection portions 516 of the first wiring layer 513. The lateral surface 522 of the semiconductor element 52 is coated with a first encapsulant 55 that is made of, e.g., an electrically insulating resin. The connection members 523 are made of gold. The connection portions 516 are coated with tin. The semiconductor element 52 is fixedly connected to the first wiring layer 513 by eutectic bonding or using anisotropic conductive paste (ACP). Since the method of connecting the connection members 523 to the connection portions 516 is well-known in the art and is not the essence of the present disclosure, the method of connection will not be elaborated hereinafter for the sake of brevity.

The printed circuit board 54 is disposed adjacent to the input end 511 of the first wiring layer 513 and includes a second wiring layer 541 that is electrically connected to the first wiring layer 513. In the first embodiment, the second wiring layer 541 is made of a material including copper.

The first heat dissipation element 542 is disposed on and connected to the printed circuit board 54, is spaced apart from the second wiring layer 541, and is made of a material including metal. Preferably, the first heat dissipation element 542 is made of a material including copper.

To be more specific, the second wiring layer 541 and the first heat dissipation element 542 may each independently be a copper-plated metal pad that is further plated with a nickel/gold (Ni/Au) layer by a surface finish process. Since gold has superior anti-oxidation properties, surface oxidation of the second wiring layer 541 and the first heat dissipation element 542 can be prevented.

The second heat dissipation element 53 has a main portion 531, a first extension portion 532 and a second extension portion 533. The main portion 531 of the second heat dissipation element 53 is disposed on and connected to one of the first or second insulation layers 514, 515. In the first embodiment, the main portion 531 is disposed on and connected to the second insulation layer 515, and corresponds in position to the semiconductor element 52. The first extension portion 532 is connected to and extends outwardly from the main portion 531 to contact the first heat dissipation element 542 on the printed circuit board 54. The second extension portion 533 is connected to and extends from the main portion 531 toward the output end 512. The second heat dissipation element 53 is made of a material including metal. In the first embodiment, the second heat dissipation element 53 is made of a material including copper, which has a thermal conductivity of about 401 W/mK.

It is worth mentioning that the first heat dissipation element 542 of the printed circuit board 54 and the second heat dissipation element 53 may each also be independently made of a material including carbon composite that has a thermal conductivity of up to 400 W/mK. Compared with the conventional aluminum heat dissipation element 13 having a thermal conductivity of 237 W/mK, the first heat dissipation element 542 and the second heat dissipation element 53 can achieve better heat dissipation and can lower process costs.

In use, an electrical signal is transmitted from the second wiring layer 541 of the printed circuit board 54, passes through the first wiring layer 513 of the flexible substrate 51, and reaches the semiconductor element 52. The semiconductor element 52 undergoes joule heating to transfer the electrical signal into heat and becomes a heat source. Since the main portion 531 of the second heat dissipation element 53 is disposed on and connected to the second insulation layer 515, and corresponds in position to the heat source (i.e., the semiconductor element 52), heat generated by the semiconductor element 52 can be effectively transferred to the first heat dissipation element 542 of the printed circuit board 54 through the first extension portion 532. Moreover, copper wirings on the printed circuit board 54 can increase the effective area of heat dissipation so as to further prevent the semiconductor element 52 from malfunctioning by being overheated.

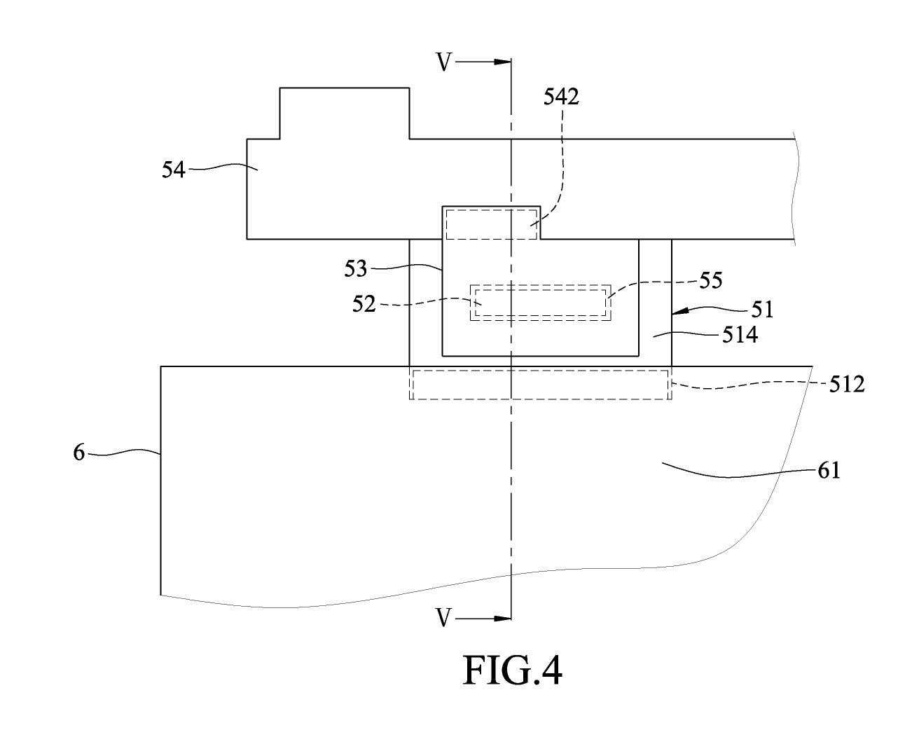

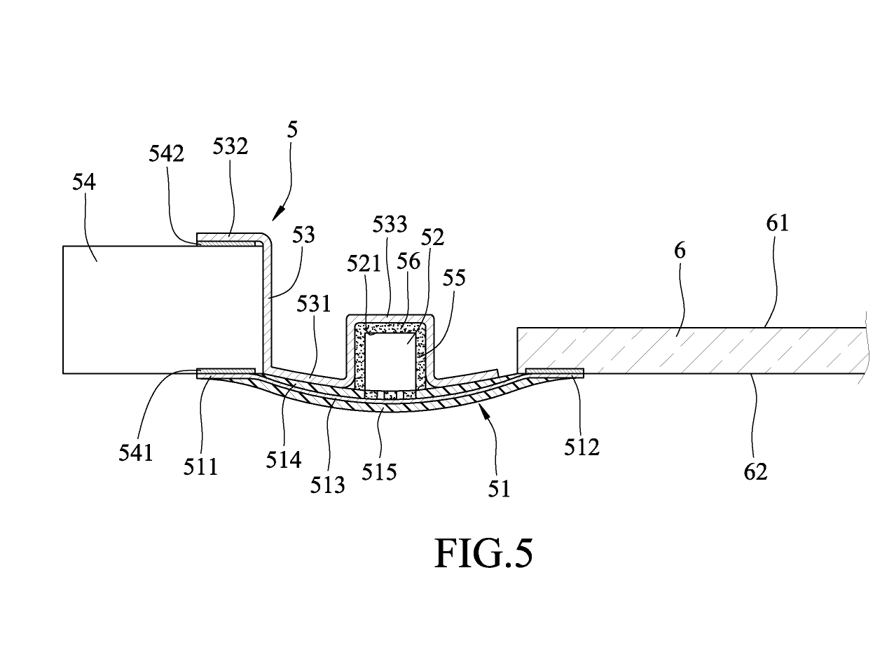

Referring to FIGS. 4 and 5, a second embodiment of the semiconductor package structure 5 has a structure similar to that of the first embodiment. The differences are described hereafter.

In the second embodiment, the top surface 521 of the semiconductor element 52 is coated with a second encapsulant 56. The second encapsulant 56 is made of an electrically insulating resin. The first heat dissipation element 542 is disposed on the printed circuit board 54 oppositely of the second wiring layer 541. The main portion 531 of the second heat dissipation element 53 is disposed on and connected to the first insulation layer 514, and is disposed between the input end 511 and the semiconductor element 52. The first extension portion 532 is connected to and extends outwardly from the main portion 531 along a lateral side of the printed circuit board 54 to contact the first heat dissipation element 542. The second extension portion 533 is connected to and extends from the main portion 531 over the first and second encapsulants 55, 56 toward the output end 512. Specifically, the second extension portion 533 covers and contacts the first and second encapsulants 55, 56 on the semiconductor element 52.

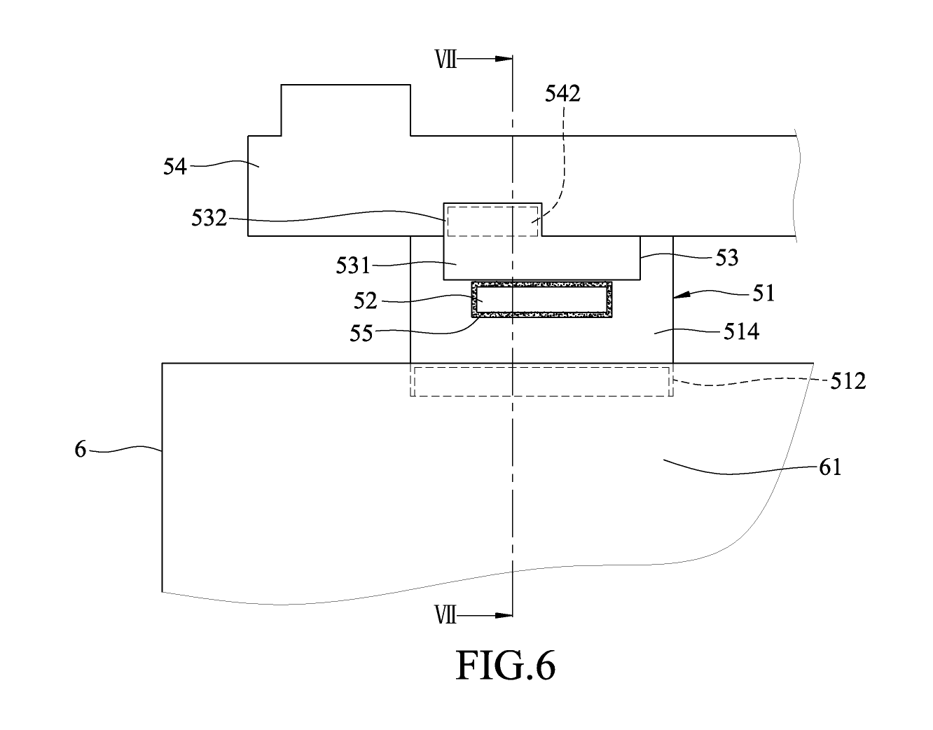

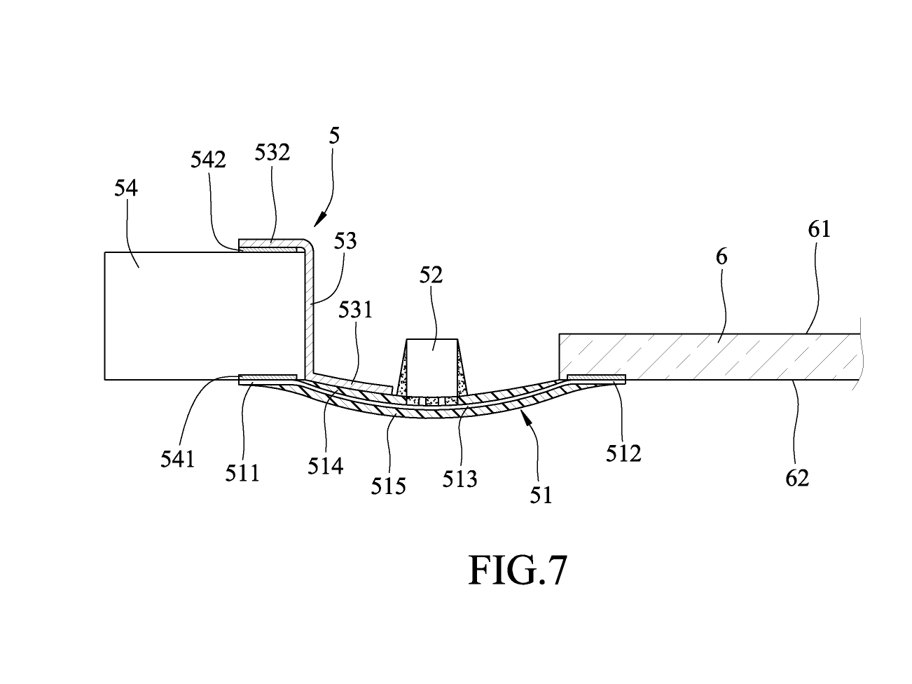

Referring to FIGS. 6 and 7, a third embodiment of the semiconductor package structure 5 has a structure similar to that of the second embodiment. The differences are described hereafter.

In the third embodiment, the second encapsulant 56 and the second extension portion 533 are omitted.

To sum up, by virtue of the first extension portion 532 of the second heat dissipation element 53 and the first heat dissipation element 542, heat generated by the semiconductor element 52 can be effectively transferred from the semiconductor element 52 to the first heat dissipation element 542 and be dissipated from the first heat dissipation element 542. The nickel/gold-plated first heat dissipation element 542 has better resistance against surface oxidation. Moreover, the copper wirings on the printed circuit board 54 can increase the effective area of heat dissipation. Therefore, the semiconductor element 52 may be effectively cooled and prevented from mal functioning due to overheating.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A semiconductor package structure comprising:
a flexible substrate including first and second insulation layers, and a first wiring layer that is disposed between said first and second insulation layers and that includes spaced-apart input and output ends;
a semiconductor element disposed on and electrically connected to said first wiring layer;
a printed circuit board disposed adjacent to said input end of said first wiring layer and including a second wiring layer that is electrically connected to said first wiring layer;
a first heat dissipation element disposed on and connected to said printed circuit board and spaced apart from said second wiring layer; and
a second heat dissipation element having a main portion that is disposed on and connected to either one of said first and second insulation layers, and a first extension portion that is connected to and extends outwardly from said main portion to contact said first heat dissipation element on said printed circuit board.

2. The semiconductor package structure as claimed in claim 1, wherein said heat dissipation member is made of a material including metal.

3. The semiconductor package structure as claimed in claim 2, wherein said heat dissipation member and said heat dissipation element are each independently made of a material including copper.

4. The semiconductor package structure as claimed in claim 1, wherein said heat dissipation member and said heat dissipation element are each independently made of a material including carbon composite.

5. The semiconductor package structure as claimed in claim 1, wherein said first wiring layer has two spaced-apart connection portions that are exposed from said first insulation layer and that are spaced apart from said input end, said semiconductor element having top and bottom surfaces, a lateral surface interconnecting said top and bottom surfaces, and two connection members that are formed on and extending from said bottom surface oppositely of said top surface to respectively contact said connection portions of said first wiring layer.

6. The semiconductor package structure as claimed in claim 5, wherein said main portion of said second heat dissipation element is disposed on and connected to said second insulation layer, and corresponds in position to said semiconductor element.

7. The semiconductor package structure as claimed in claim 5, wherein said first wiring layer further includes an output end spaced apart from said input end, said semiconductor element being disposed between said input and output ends, said second heat dissipation element further having a second extension portion that extends from said main portion toward said output end.

8. The semiconductor package structure as claimed in claim 5, wherein said lateral surface is coated with a first encapsulant.

9. The semiconductor package structure as claimed in claim 8, wherein said main portion of said second heat dissipation element is disposed on and connected to said first insulation layer, and disposed between said input end and said semiconductor element.

10. The semiconductor package structure as claimed in claim 9, wherein said top surface of said semiconductor element is coated with a second encapsulant, said second heat dissipation element further having a second extension portion that is connected to and extends from said main portion and that covers and contacts said first and second encapsulants on said semiconductor element.

11. The semiconductor package structure as claimed in claim 10, wherein said first wiring layer further includes an output end spaced apart from said input end, said semiconductor element being disposed between said input and output ends, said second extension portion of said second heat dissipation element extending from said main portion over said first and second encapsulants toward said output end.
